(19) United States
(12) Patent Application Publication
(10) Pub. No.: US 2005/0009234 A1
(43) Pub. Date: Jan. 13, 2005

(54) Stacked module systems and methods for CSP packages

(75) Inventors: Julian Partridge, Austin, TX (US); James Douglas Wehrly JR., Austin, TX (US); Julian Dowden, Austin, TX (US); David L. Roper, Austin, TX (US); James W. Cady, Austin, TX (US)

Correspondence Address: J. Scott Denko;Andrews & Kurth, L.L.P., 111 Congress Ave., Suite 1700, Austin, TX, 78701, US

(73) Assignee: Staktek Group, L.P.

(21) Appl. No.: 10/913,220

(22) Filed: Aug. 6, 2004

Related U.S. Application Data
(63) Continuation-in-part of application No. 10/836,855, filed on Apr. 30, 2004.
Application No. 10/836,855 is a continuation-in-part of application No. 10/453,398, filed on Jun. 3, 2003.
Application No. 10/836,855 is a continuation-in-part of application No. PCT/US03/29000, filed on Sep. 15, 2003.
Application No. PCT/US03/29000 is a continuation-in-part of application No. 10/453,398, filed on Jun. 3, 2003.
Application No. 10/453,398 is a continuation-in-part of application No. 10/005,581, filed on Oct. 26, 2001, now Pat. No. 6,576,992.

(51) Int. Cl. H01L 21/44; H01L 23/02

(52) U.S. Cl. 438/109; 257/777; 257/686

(57) ABSTRACT

The present invention stacks chip scale-packaged integrated circuits (CSPs) into modules that conserve PWB or other board surface area. Multiple numbers of CSPs may be stacked in accordance with the present invention. The CSPs employed in stacked modules devised in accordance with the present invention are connected with flex circuitry. A form standard is disposed along a planar surface of a CSP. The form standard provides a physical form that allows many of the varying package sizes found in the broad family of CSP packages to be used to advantage while employing a standard connective flex circuitry design. The form standard achieves a reduced profile after the CSP has been attached to the form standard. In addition, in constructing modules in accordance with some preferred modes of the invention, CSP contacts are reduced in height to create lower profile modules. Thus, low profile embodiments of the modules of the present invention are devised.

### RELATED APPLICATIONS

This application is a continuation-in-part of U.S. patent application Ser. No. 10/836,855, filed Apr. 30, 2004, which is a continuation in part of both U.S. patent application Ser. No. 10/453,398, filed Jun. 3, 2003 and PCT App. No. PCT/US03/29000, filed Sep. 15, 2003. PCT App. No. PCT/US03/29000, filed Sep. 15, 2003 is a continuation in part of U.S. patent application Ser. No. 10/453,398, filed Jun. 3, 2003 which is a continuation-in-part of U.S. patent application Ser. No. 10/005,581, filed Oct. 26, 2001, now U.S. Pat. No. 6,576,992.

U.S. patent application Ser. No. 10/836,855, filed Apr. 30, 2004, is hereby incorporated by reference.

### TECHNICAL FIELD

1. Technical Field

The present invention relates to aggregating integrated circuits and, in particular, to stacking integrated circuits in chip-scale packages.

2. Background of the Invention

A variety of techniques are used to stack packaged integrated circuits. Some methods require special packages, while other techniques stack conventional packages.

Leaded packages play an important role in electronics, but efforts to miniaturize electronic components and assemblies have driven development of technologies that preserve circuit board surface area. Because leaded packages have leads emergent from peripheral sides of the package, leaded packages occupy more than a minimal amount of circuit board surface area. Consequently, alternatives to leaded packages known as chip scale packaging or “CSP” have recently gained market share.

CSP refers generally to packages that provide connection to an integrated circuit through a set of contacts (often embodied as “bumps” or “balls”) arrayed across a major surface of the package. Instead of leads emergent from a peripheral side of the package, contacts are placed on a major surface and typically emerge from the planar bottom surface of the package. The absence of “leads” on package sides renders most stacking techniques devised for leaded packages inapplicable for CSP stacking.

A variety of previous techniques for stacking CSPs typically present complex structural arrangements and thermal or high frequency performance issues. For example, thermal performance is a characteristic of importance in CSP stacks. Further, many stacking techniques result in modules that exhibit profiles taller than may be preferred for particular applications.

A variety of stacked module designs from the assignee of the present invention exhibit low profiles that are achieved with use of a variety of methods, techniques and components. At the same time, some such modules exploit the present assignee's innovations in connective adaptability and thermal management provided by the use of form standards that allow flex circuitry to adapt to many different sizes of CSPs while providing thermal performance improvement. However, further techniques for low profile realization are welcome additions to CSP stacking technologies.

What is provided, therefore, is a technique and system for stacking CSPs that provides a thermally efficient, reliable structure that performs well at higher frequencies but does not add excessive height to the stack yet allows production at reasonable cost with readily understood and managed materials and methods.

### SUMMARY OF THE INVENTION

The present invention stacks chip scale-packaged integrated circuits (CSPs) into modules that conserve PWB or other board surface area. Although the present invention is applied most frequently to chip scale packages that contain one die, it may be employed with chip scale packages that include more than one integrated circuit die.

Multiple numbers of CSPs may be stacked in accordance with the present invention. The CSPs employed in stacked modules devised in accordance with the present invention are connected with flex circuitry. That flex circuitry may exhibit one or two or more conductive layers with preferred embodiments having two conductive layers.

A form standard is disposed along a planar surface of a CSP. The form standard provides a physical form that allows many of the varying package sizes found in the broad family of CSP packages to be used to advantage while employing a standard connective flex circuitry design. In a preferred embodiment, the form standard will be devised of heat transference material such as copper, for example, to improve thermal performance.

The form standard achieves a reduced profile after the CSP has been attached to the form standard material. In addition, in constructing modules in accordance with some preferred modes of the invention, CSP contacts are reduced in height to create lower profile modules. With some of the preferred methods of the present invention, the compressed contacts mix with solder paste and set beneficially as lower diameter contacts. Thus, low profile embodiments of the present invention are devised.

### SUMMARY OF THE DRAWINGS

FIG. 1 is an elevation view of a high-density circuit module devised in accordance with a preferred two-high embodiment of the present invention.

FIG. 2 depicts, in enlarged view, the area marked “A” in FIG. 1.

FIG. 3A depicts a part of an exemplar CSP before its incorporation into a preferred embodiment of the present invention.

FIG. 3B depicts a part of an exemplar CSP after one of its contacts has been reduced in height according to a preferred mode of the present invention.

FIG. 4 depicts a combination of a CSP and an attached form standard before the form standard has been reduced in profile according to a preferred mode of the present invention.

FIG. 5 depicts a deformation area in a form standard employed in a preferred embodiment of the present invention.

FIG. 6 illustrates a preferred construction method that may be employed in making a high-density module devised in accordance with a preferred embodiment of the present invention.

FIG. 7 depicts a series of exemplar forming tools that may be employed in preferred modes of the present invention.

FIG. 8 depicts a preferred construction that may be employed in a preferred embodiment of the present invention.

FIG. 9 depicts another preferred construction that may be employed in a preferred embodiment of the present invention.

FIG. 10 depicts a sectional view of a connective area and a layered construction for a preferred flex circuitry employed in a preferred embodiment of the present invention.

FIG. 11 depicts a sectional view of a connective area and layered construction for an alternative preferred flex circuitry employed in a preferred embodiment of the present invention.

FIG. 12 depicts a unit that may be used to advantage in preferred embodiments of the present invention.

FIG. 13 depicts a preferred embodiment for a process and system for achieving a low profile embodiment of the present invention.

### DESCRIPTION OF PREFERRED EMBODIMENTS

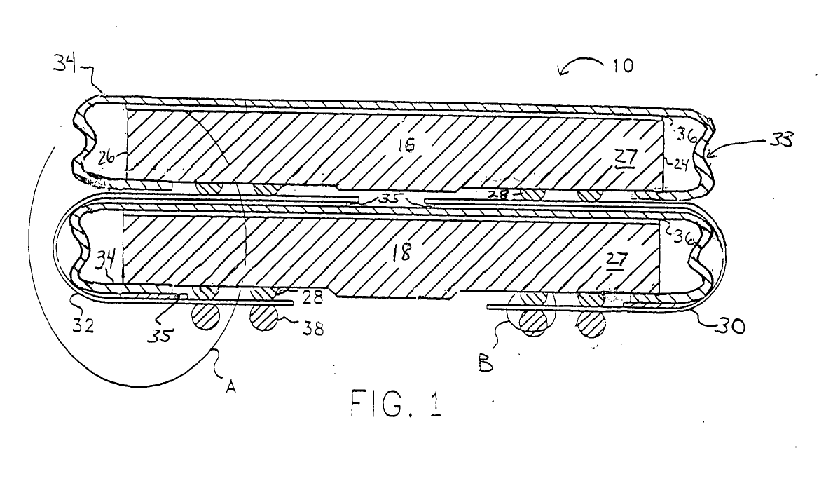

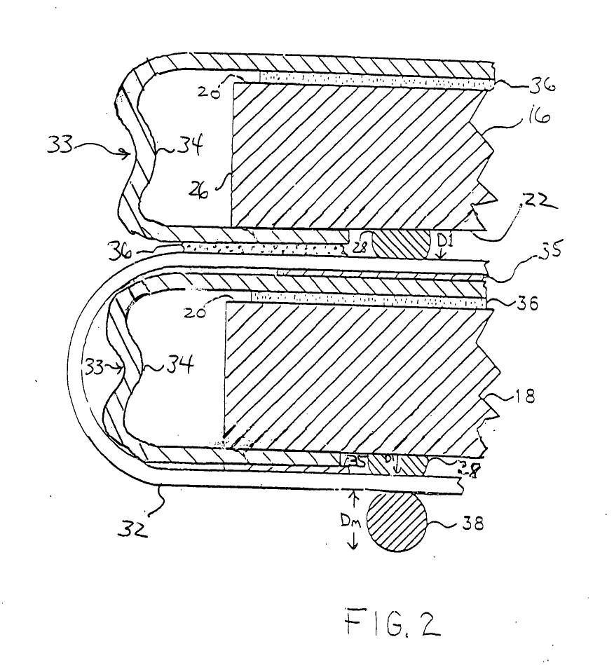

FIG. 1 shows a two-high module 10 devised in accordance with a preferred embodiment of the invention. FIG. 1 has an area marked “A” that is subsequently shown in enlarged depiction in FIG. 2. Module 10 is comprised of two CSPs: CSP 16 and CSP 18. Each of the CSPs has an upper surface 20 and a lower surface 22 and opposite lateral edges 24 and 26 and typically include at least one integrated circuit surrounded by a plastic body 27. The body need not be plastic, but a large majority of packages in CSP technologies are plastic. Those of skill will realize that the present invention may be devised to create modules with different size CSPs and that the constituent CSPs may be of different types within the same module 10. For example, one of the constituent CSPs may be a typical CSP having lateral edges 24 and 26 that have an appreciable height to present a “side” while other constituent CSPs of the same module 10 may be devised in packages that have lateral edges 24 and 26 that are more in the character of an edge rather than a side having appreciable height.

The term CSP should be broadly considered in the context of this application. Collectively, these will be known herein as chip scale packaged integrated circuits (CSPs) and preferred embodiments will be described in terms of CSPs, but the particular configurations used in the explanatory figures are not, however, to be construed as limiting. For example, the elevation views are depicted with CSPs of a particular profile known to those in the art, but it should be understood that the figures are exemplary only. The invention may be employed to advantage in the wide range of CSP configurations available in the art where an array of connective elements is available from at least one major surface. The invention is advantageously employed with CSPs that contain memory circuits, but may be employed to advantage with logic and computing circuits where added capacity without commensurate PWB or other board surface area consumption is desired.

Typical CSPs, such as, for example, ball-grid-array (“BGA”), micro-ball-grid array, and fine-pitch ball grid array (“FBGA”) packages have an array of connective contacts embodied, for example, as leads, bumps, solder balls, or balls that extend from lower surface 22 of a plastic casing in any of several patterns and pitches. An external portion of the connective contacts is often finished with a ball of solder. Shown in FIG. 1 are contacts 28 along lower surfaces 22 of the illustrated constituent CSPs 16 and 18. Contacts 28 provide connection to the integrated circuit or circuits within the respective packages.

In FIG. 1, flex circuitry (“flex”, “flex circuits” or “flexible circuit structures”) is shown connecting constituent CSPs 16 and 18. A single flex circuit may be employed in place of the two depicted flex circuits 30 and 32. The entirety of the flex circuitry may be flexible or, as those of skill in the art will recognize, a PCB structure made flexible in certain areas to allow conformability around CSPs and rigid in other areas for planarity along CSP surfaces may be employed as an alternative flex circuit in the present invention. For example, structures known as rigid-flex may be employed.

A first form standard 34 is shown disposed adjacent to and along upper surface 20 of CSP 18. A second form standard is also shown associated with CSP 16. Both the first and second form standards 34 exhibit deformation area 33 which provides an area for compressive deformation of form standard 34. When form standard 34 is compressed about or fitted to CSP 18, for example, after being attached to CSP 18 along upper surface 20, compressive forces are applied to result in a profile reduction for the combination of CSP and form standard. Form standard 34 may be fixed to upper surface 20 of the respective CSP with an adhesive 36 which preferably is thermally conductive. A form standard may be employed on each CSP in module 10 for heat extraction enhancement as shown in the depiction of FIG. 1 which is a preferred mode for the present invention where heat extraction is a priority. In other embodiments, form standard 34 may be inverted relative to the corresponding CSP.

Form standard 34 is, in a preferred embodiment, devised from copper to create, as shown in the depicted preferred embodiment of FIG. 1, a mandrel that mitigates thermal accumulation while providing a standard-sized form about which flex circuitry is disposed. Form standard 34 may also be devised from nickel-plated copper in preferred embodiments. Form standard 34 may take other shapes and forms such as, for example, an angular “cap” that rests upon the respective CSP body. It also need not be thermally enhancing although such attributes are preferable. The form standard 34 allows the invention to be employed with CSPs of varying sizes, while articulating a single set of connective structures useable with the varying sizes of CSPs. Thus, a single set of connective structures such as flex circuits 30 and 32 or a single flexible circuit in the mode where a single flex is used in place of the flex circuit pair 30 and 32 may be devised and used with the form standard 34 method and/or systems disclosed herein to create stacked modules with CSPs having different sized packages. This will allow the same flex circuitry set design to be employed to create iterations of a stacked module 10 from constituent CSPs having a first arbitrary dimension X across attribute Y (where Y may be, for example, package width), as well as modules 10 from constituent CSPs having a second arbitrary dimension X prime across that same attribute Y. Thus, CSPs of different sizes may be stacked into modules 10 with the same set of connective structures (i.e., flex circuitry). Further, as those of skill will recognize, mixed sizes of CSPs may be implemented into the same module 10, such as would be useful to implement embodiments of a system-on-a-stack where CSPs of various sizes and functions are aggregated in a stack.

In one preferred embodiment, portions of flex circuits 30 and 32 are fixed to form standard 34 by bonds 35 which are, in some preferred modes, metallurgical bonds created by placing on form standard 34, a first metal layer such as tin, for example, which, when melted, combines with a second metal that was placed on the flex circuitry or is part of the flex circuitry (such as the gold plating on a conductive layer of the flex) to form a higher melting point intermetallic bond that will not remelt during subsequent reflow operations as will be described further.

FIG. 2 depicts in enlarged view, the area marked “A” in FIG. 1. FIG. 2 illustrates in a preferred embodiment, an arrangement of a form standard 34 and its relation to flex circuitry 32 in a two-high module 10 that employs a form standard 34 with each of CSPs 16 and 18. The depicted form standards exhibit deformation areas 33. Later figures illustrate exemplar preferred internal layer constructions of flex circuitry. Shown in greater detail than in FIG. 1, are bonds 35 that will be described with reference to later Figs. Also shown in FIG. 2, is an application of adhesive 36 between form standards 34 and CSPs 18 and 16. In a preferred embodiment, an adhesive 36 may also be employed between form standard 34 associated with CSP 16 and the flex circuitry 32. Adhesive 36 will preferably be thermally conductive.

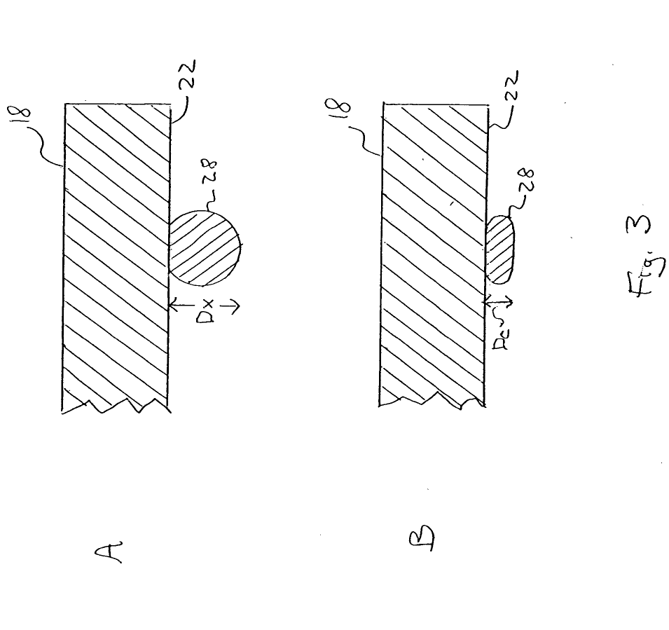

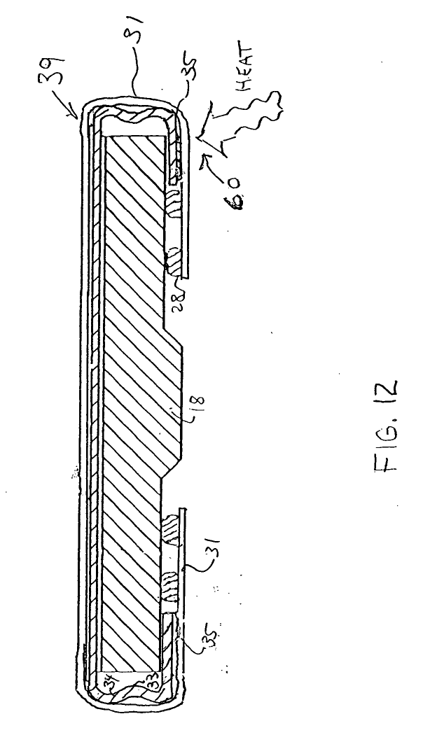

Although those of skill will recognize that the Figs. are not drawn to scale, the contacts 28 of CSPs 16 and 18 have been shown to have (although need not exhibit) a limited height above the lower surface 22 of the corresponding CSP. FIG. 3A depicts a contact 28 of CSP 18 before that contact 28 has undergone the step of height reduction described further subsequently. As shown, contact 28 rises a height Dx above surface 22 of CSP 18. FIG. 3B depicts contact 28 after the step of height reduction described further subsequently. In FIG. 3B, the height reduction was conducted before attachment of a form standard 34 to CSP 18. Height reduction of contacts 28 may occur either before or after attachment of a form standard 34 to CSP 18. As shown, contact 28 rises a height Dc above surface 22 of CSP 18. With reference to FIG. 2, in some embodiments, contacts 28 may rise a height D1 above said surface 22 after incorporation of CSP 18 into module 10 or later shown unit 39 (FIG. 12.). In the preferred embodiment, height D1 is greater than the height Dc such contacts exhibit after the step of contact height reduction, but before attachment of flex circuitry. Even so, in preferred embodiments, height D1 of contacts 28 after CSP 18 is incorporated into a module 10 (such as shown in FIG. 2) or in later shown unit 39 is less than height Dx which is the height above surface 22 exhibited by a CSP contact 28 before incorporation of CSP 18 into either later shown unit 39 or module 10 and before contact height reduction according to preferred modes of the present invention. As shown in FIG. 2, module contacts 38 rise a height of Dm from flex circuit 32 and, in preferred embodiments of module 10, D1 is less than Dm.

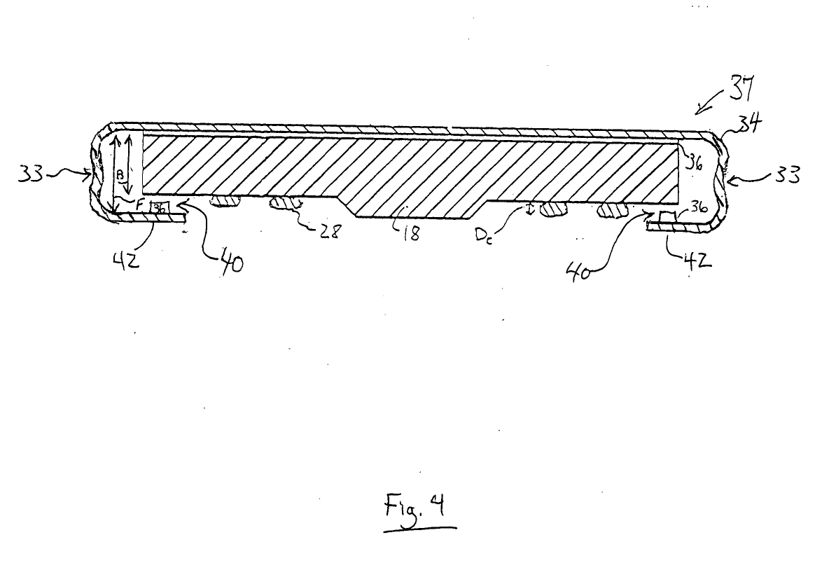

With reference to FIG. 4, combination 37 is depicted as consisting of form standard 34 attached to CSP 18. FIG. 4 illustrates combination 37 after form standard 34 and CSP 18 are attached to each other, but before a final configuration for form standard 34 has been imposed to present a reduced profile for combination 37. The attachment of form standard 34 to CSP 18 may be realized in a variety of ways such as, for example, with an adhesive depicted by reference 36 which is preferably a film adhesive that is applied by heat tacking.

As shown in FIG. 4, combination 37 exhibits “gaps” 40 between lower surface 22 of CSP 18 and flanges 42 of form standard 34. Gaps 40 allow edge-wise insertion of the CSP into the form standard. In typical assembly techniques useful in construction of module 10 embodiments, a preformed form standard 34 is employed that is dimensioned to provide gaps 40 to allow sufficient play between the body 27 of CSP 18 (having dimension B) and the preconfigured dimension F of form standard 34 to allow a CSP to be inserted into form standard 34. Optional adhesive 36 is shown on flanges 42 proximal to CSP 18. The CSP is typically edge-wise inserted into the form standard 34 and then attachment between form standard 34 and CSP 18 is realized. An even lower profile may be realized, however, by use of the preferred methods of the present invention related to post-attachment deformation or fitting of form standard 34.

In FIG. 4, form standard 34 is shown having deformation area 33 which provides an area for compressive deformation of form standard 34. When form standard 34 is compressed about or fitted to CSP 18 after the attachment of form standard 34 to CSP 18, compressive forces are applied to form standard 34 across dimension F to narrow gaps 40 resulting in profile reduction for combination 37 and, consequently, a lower profile module 10. A variety of techniques are known that may be adapted to provide a compressive or fitting function appropriate for imposing a lower profile on combination 37 in accordance with preferred modes of the present invention and clamping or squeezing techniques having forces appropriate for the materials chosen for form standard 34 and CSP 18 may be readily determined without resort to undue experimentation.

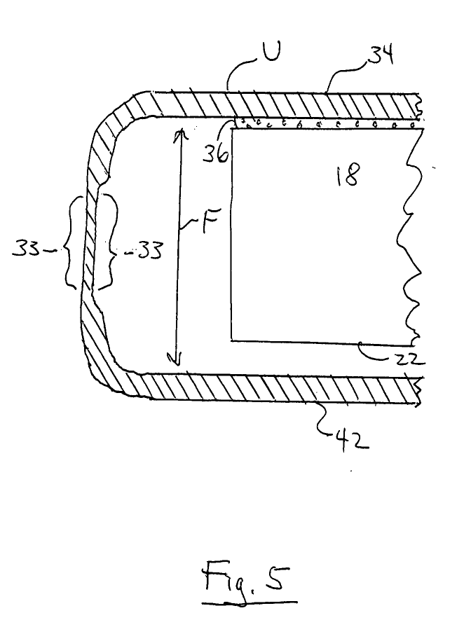

FIG. 5 depicts an alternative embodiment for a form standard 34 in accordance with the present invention. In the depicted form standard, deformation area 33 is a narrowed extent of form standard material that will, predictably deform when dimension F is placed under deformative force. Thus, flange 42 and lower surface 22 of CSP 18 approach and flange 42 and the upper length U of form standard 34 preferably remain substantially parallel.

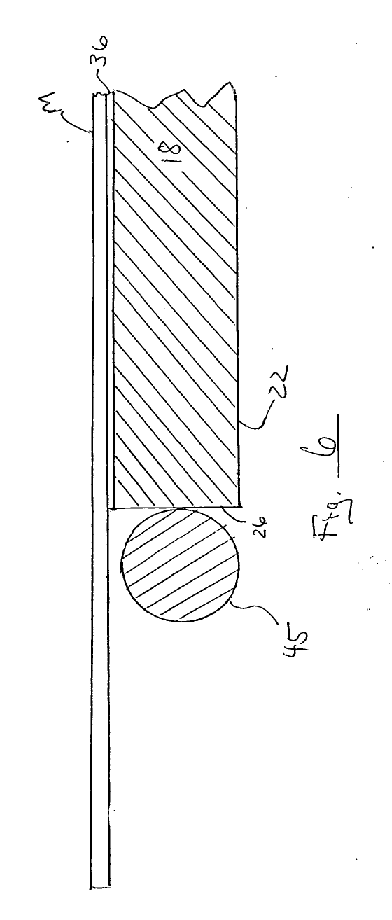

As those of skill will recognize after appreciating this disclosure, other techniques are available to provide low profile-configured combinations appropriate for use in embodiments of module 10. FIG. 6, for example, depicts a forming tool 45 about which a metallic material member “M” may be deformed or bent to create form standard 34. Metallic member M is attached to CSP 18 with adhesive 36 prior to deformation about forming tool 45. Although the Figs. herein recite use of CSP 18 as an exemplar, the methods and systems disclosed herein may be employed to advantage with the variety of CSPs that may be employed in embodiments of the present invention whether at lower or upper levels in modules 10.

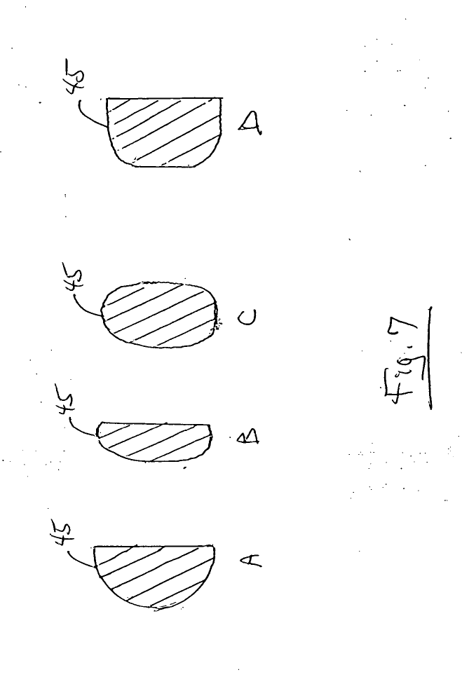

FIG. 7 depicts a variety of exemplar shapes that may be employed as forming tools 45 in accordance with the present invention. These are merely example shapes and once the principles are understood, those of skill will be able to select appropriate tools 45 for use in forming form standards in accordance with the invention.

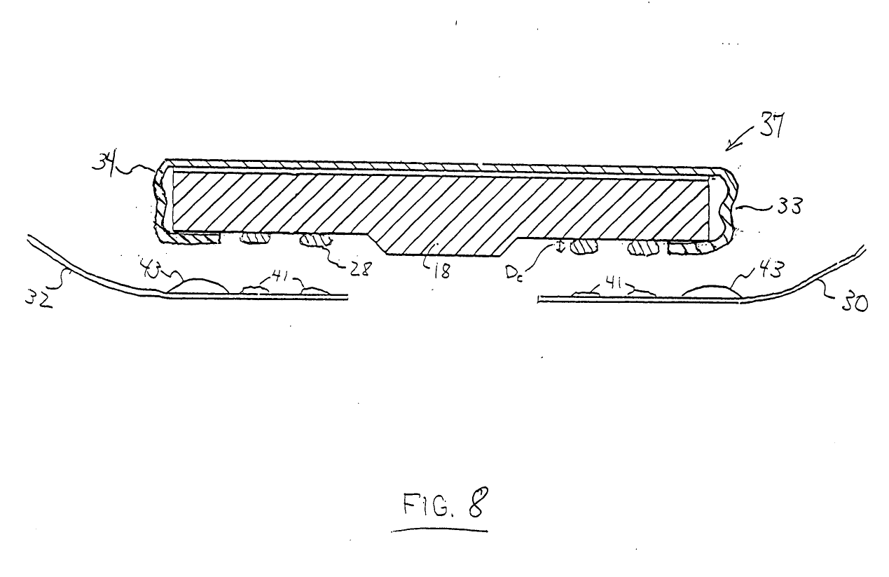

As shown in FIG. 8, flex circuits 30 and 32 are prepared for attachment to combination 37 by the application of solder paste 41 at sites that correspond to contacts 28 of CSP 18 to be connected to the flex circuitry. Also shown are glue applications indicated by references 43 which are, when glue is employed to attach form standard 34 to the flex circuitry, preferably liquid glue. As shown and, as earlier described, form standard 34 has been configured to allow combination 37 to express a lowered profile.

As shown in this embodiment, contacts 28 of CSP 18 have height Dc which is less than height D1 shown in earlier FIG. 2. The depicted contacts 28 of CSP 18 are reduced in height by compression or other means of height reduction before attachment of combination 37 to the flex circuitry. This compression may be done before or after attachment of form standard 34 and CSP 18 with after-attachment compression being preferred. Contacts 28 may be reduced in height while in a solid or semi-solid state. Unless reduced in height, contacts 28 on CSP 18 tend to “sit-up” on solder paste sites 41 during creation of module 10. This causes the glue line between the flex circuitry and form standard 34 to be thicker than may be desired. The glue reaches to fill the gap between the flex and form standard 34 that results from the distancing of the attached form standard 34 from the flex by the contacts 28 “sitting” upon the solder paste sites 41.

With a thicker glue line between flex and form standard 34, upon reflowing, the solder in contacts 28 mixes with solder paste 41 and reaches to span the space between CSP 18 and the flex circuitry which is now a fixed distance away from CSP 18. This results in a larger vertical dimension for contact 28 than is necessary due to the higher glue line and, consequently, a module 10 with a taller profile. The higher glue line was created by not reducing the contact diameters before attachment of the flex circuitry to the form standard 34 (or the form standard part of combination 37). With the preferred methods of the present invention, however, upon reflow, the compressed contacts 28 mix with solder paste 41 and set beneficially as lower diameter contacts 28. The resulting unit combining combination 37 with flex circuitry may then be employed to create low profile embodiment of module 10. With the low-profile configured form standard 34 and the methods described herein, lower profile modules 10 in accordance with preferred embodiments of the present invention may be devised.

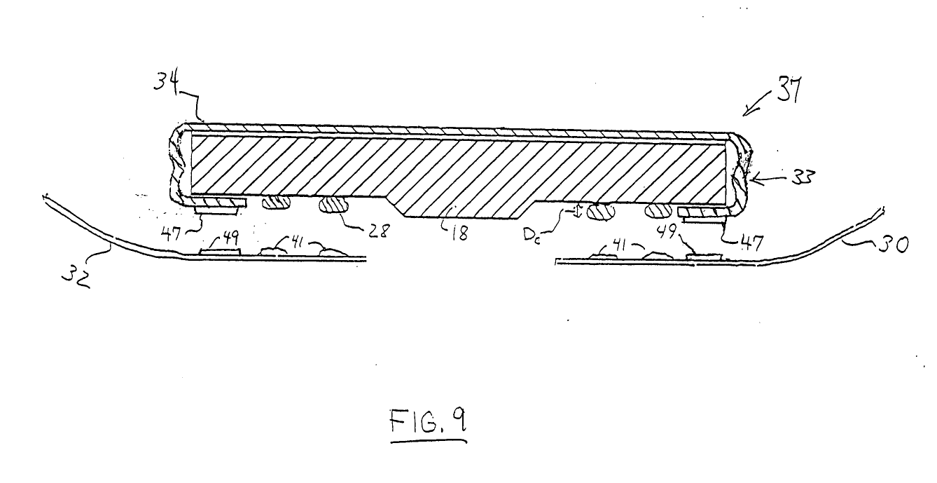

FIG. 9 depicts a preferred alternative and additional method to reduce module 10 height while providing a stable bond 35 between form standard 34 and the flex circuitry. As depicted, combination 37 employing form standard 34 expressing a post-attachment low profile configuration is to be attached to flex circuitry to create a low profile unit adaptable for use in preferred low profile embodiments of the present invention. The preferable bonds 35 that were earlier shown in FIG. 1 may be created by the following technique. As shown in FIG. 9, a first metallic material indicated by reference 47 has been layered on, or appended or plated to form standard 34. A second metallic material represented by reference 49 on flex circuit 30 is provided by, for example, applying a thin layer of metal to flex circuit 30 or, by exposing part of a conductive layer of the flex circuit. When form standard 34 is brought into proximity with the flex circuitry, and localized heating is applied to the area where the first and second metals 47 and 49 are adjacent, an intermetallic bond 35 is created. A preferred metallic material 47 would be a thin layer of tin applied to create a layer about 0.0005″. When melted to combine with the gold of a conductive layer of flex circuitry exposed at that, for example, site, the resulting intermetallic bond 35 will have a higher melting point resulting in the additional advantage of not re-melting during subsequent re-flow operations at particular temperatures.

A variety of methods may be used to provide the localized heating appropriate to implement the metallic bonding described here including localized heat application with which many in the art are familiar as well as ultrasonic bonding methods where the patterns in the flex circuitry are not exposed to the vibration inherent in such methods and the metals chosen to implement the bonds have melting points within the range achieved by the ultrasonic method.

The creation of intermetallic bonds may also be employed to bond combination 37 to flex circuitry along other sites where form standard 34 and flex circuitry are adjacent such as, for example, on sites or continuously along the upper extent of form standard where typically glue is otherwise applied to further fasten flex circuitry to form standard 34. The intermetallic bonding described here may be employed alone or with other methods such as the post-attachment deformations or formation of form standard 34 and/or the contact compression techniques described herein to create instances of module 10 that present a low profile.

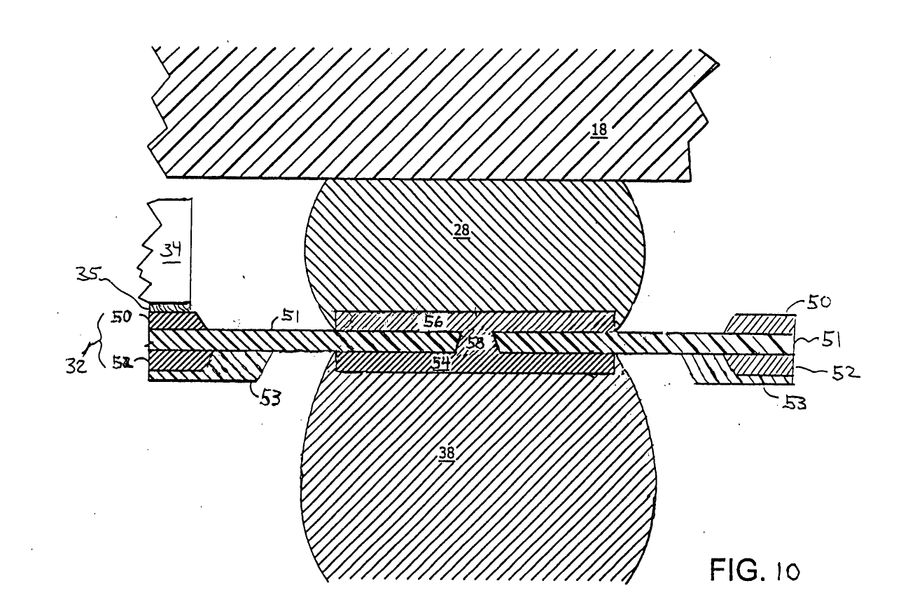

FIG. 10 is a cross-sectional view of a portion of a preferred embodiment depicting a preferred construction for flex circuitry which, in the depicted embodiment is, in particular, flex circuit 32 which comprises two conductive layers 50 and 52 separated by intermediate layer 51. Preferably, the conductive layers are metal such as alloy 110.

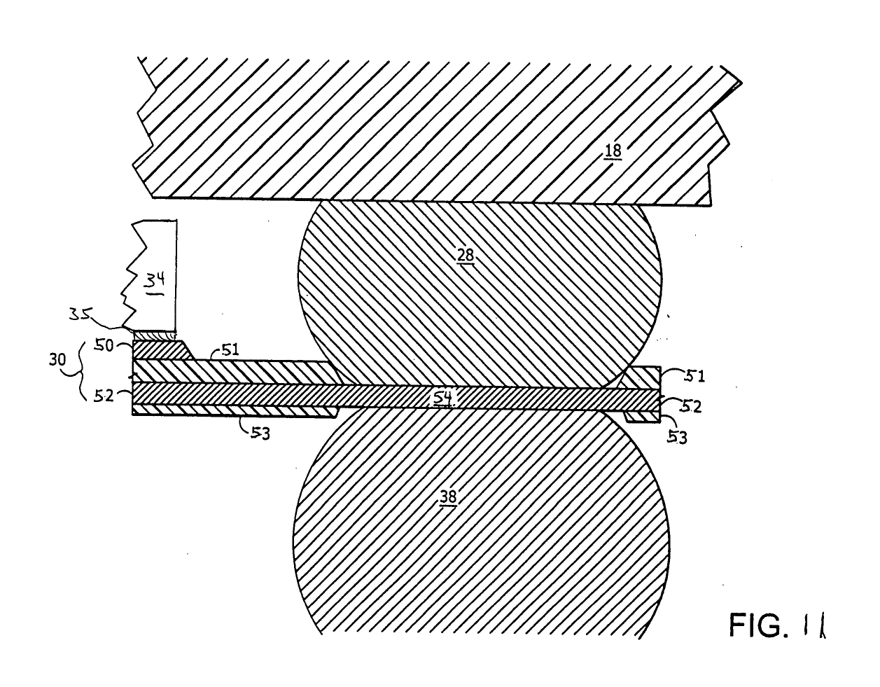

With continuing reference to FIG. 10, optional outer layer 53 is shown over conductive layer 52 and, as those of skill will recognize, other additional layers may be included in flex circuitry employed in the invention, such as a protective inner layer over conductive layer 50, for example. Flex circuits that employ only a single conductive layer such as, for example, those that employ only a layer such as conductive layer 52 may be readily employed in embodiments of the invention. The use of plural conductive layers provides, however, advantages and the creation of a distributed capacitance across module 10 intended to reduce noise or bounce effects that can, particularly at higher frequencies, degrade signal integrity, as those of skill in the art will recognize. In the depicted preferred embodiment, flex contact 54 at the level of conductive layer 52 and flex contact 56 at the level of conductive layer 50 provide contact sites to allow connection of module contact 38 and CSP contact 28 through via 58. Form standard 34 is seen in the depiction of FIG. 10 attached to conductive layer 50 of flex circuit 30 with metallic bond 35. FIG. 11 depicts a cross-sectional view of an alternative preferred construction in a contact area in a module 10 in accordance with a preferred embodiment of the invention.

FIG. 12 depicts unit 39 comprised from flex circuitry 31 which, in this depicted embodiment, is a single flex circuit, and form standard 34 and CSP 18. Heat is shown as being applied to area 60 where the first metallic material 47 and second metallic material 49 were made adjacent by bringing combination 37 and flex circuitry 31 together.

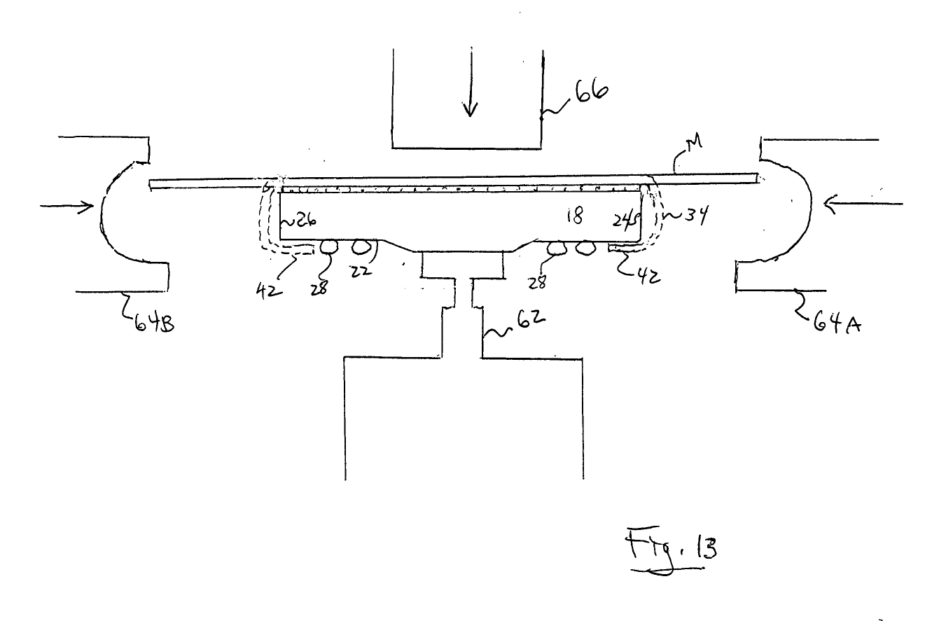

FIG. 13 depicts another preferred technique and system for post-attachment formation of form standard-CSP combinations that may present a low profile and be used to advantage in modules 10 according to preferred embodiments of the present invention.

As shown, pedestal 62 supports CSP 18 to which metallic member M has been attached. Press members 64A and 64B move laterally toward CSP 18 and attached metallic member M, the combination of which is held in position by press 66. Depicted press members 64A and 64B exhibit cavities 68A and 68B, respectively, to impart appropriate dimensional form to metallic member M and thereby configure a form standard 34 (depicted with dotted line) about lateral edges 24 and 26 of CSP 18 and bring flanges 42 of form standard 34 beneath lower surface 22 of CSP 18.

Although the present invention has been described in detail, it will be apparent to those skilled in the art that the invention may be embodied in a variety of specific forms and that various changes, substitutions and alterations can be made without departing from the spirit and scope of the invention. The described embodiments are only illustrative and not restrictive and the scope of the invention is, therefore, indicated by the following claims.

1. A method for devising a combination for use in a high-density circuit module, the method comprising the steps of:
providing a first CSP having first and second lateral sides and upper and lower major surfaces;
providing a form standard having a flange;
attaching the form standard to the first CSP to dispose the form standard along and adjacent to the upper major surface and about the first lateral side of the first CSP to dispose the flange beneath the lower major surface of the first CSP while leaving a gap between the lower major surface of the first CSP and the flange; and
reducing the size of the gap.

2. The method of claim 1 further comprising the step of attaching flex circuitry to the combination.

3. The method of claim 2 in which the flex circuitry comprises at least two conductive layers.

4. The method of claim 2 in which the flex circuitry comprises two flex circuits.

5. The method of claim 3 in which the flex circuitry comprises two flex circuits.

6. The method of claim 2 in which the step of attaching the flex circuitry to the combination is realized with at least one metallic bond.

7. The method of claim 3 in which the step of attaching the flex circuitry to the combination is realized with at least one metallic bond.

8. The method of claim 4 in which the step of attaching the flex circuitry to the combination is realized with at least one metallic bond.

9. The method of claim 2 in which the first CSP further has CSP contacts on the lower major surface, the CSP contacts rising from the lower major surface by a height H; and the method further comprises the step of
reducing the height H of the CSP contacts.

10. The method of claim 3 in which the first CSP further has CSP contacts on the lower major surface, the CSP contacts rising from the lower major surface by a height H; and the method further comprises the step of
reducing the height H of the CSP contacts.

11. The method of claim 6 in which the first CSP further has CSP contacts on the lower major surface, the CSP contacts rising from the lower major surface by a height H; and the method further comprises the step of
reducing the height H of the CSP contacts.

12. The method of claim 7 in which the first CSP further has CSP contacts on the lower major surface, the CSP contacts rising from the lower major surface by a height H; and the method further comprises the steps of
reducing the height H of the CSP contacts.

12. A method for devising a high density circuit module, the method comprising the steps of:
providing a first CSP having first and second lateral sides and upper and lower major surfaces;
providing a form standard having a flange;
attaching the form standard to the first CSP to dispose the form standard along and adjacent to the upper major surface and about the first lateral side of the first CSP to dispose the flange beneath the lower major surface of the first CSP while leaving a gap between the lower major surface of the first CSP and the flange;
reducing the size of the gap; and
disposing a second CSP above the first CSP.

14. The method of claim 13 further comprising the step of attaching flex circuitry to the form standard.

15. The method of claim 14 in which the flex circuitry comprises at least two conductive layers.

16. The method of claim 14 in which the flex circuitry comprises two flex circuits.

17. The method of claim 15 in which the flex circuitry comprises two flex circuits.

18. The method of claim 14 in which the flex circuitry is attached to the form standard with at least one metallic bond.

19. The method of claim 15 in which the flex circuitry is attached to the form standard with at least one metallic bond.

20. The method of claim 16 in which the two flex circuits are each attached to the form standard with at least one metallic bond.

21. The method of claim 17 in which the two flex circuits are each attached to the form standard with at least one metallic bond.

22. The method of claim 13 in which the first CSP further has CSP contacts on its lower major surface, the CSP contacts rising from the lower major surface of the first CSP by a height H; and the method further comprises the step of
reducing the height H of the CSP contacts of the first CSP.

23. The method of claim 14 in which the first CSP further has CSP contacts on its lower major surface, the CSP contacts rising from the lower major surface of the first CSP by a height H; and the method further comprises the step of
reducing the height H of the CSP contacts of the first CSP.

24. The method of claim 15 in which the first CSP further has CSP contacts on its lower major surface, the CSP contacts rising from the lower major surface of the first CSP by a height H; and the method further comprises the step of
reducing the height H of the CSP contacts of the first CSP.

25. The method of claim 16 in which the first CSP further has CSP contacts on its lower major surface, the CSP contacts rising from the lower major surface of the first CSP by a height H; and the method further comprises the step of
reducing the height H of the CSP contacts of the first CSP.

26. The method of claim 17 in which the first CSP further has CSP contacts on its lower major surface, the CSP contacts rising from the lower major surface of the first CSP by a height H; and the method further comprising the step of
reducing the height H of the CSP contacts of the first CSP.

27. A method for devising a high density circuit module, the method comprising the steps of:
providing a first CSP having first and second lateral sides and upper and lower major surfaces;
providing a first form standard having a flange;
attaching the first form standard to the first CSP to dispose the first form standard along and adjacent to the upper major surface and about the first lateral side of the first CSP to dispose the flange of the first form standard beneath the lower major surface of the first CSP while leaving a gap between the lower major surface of the first CSP and the flange of the first form standard;
reducing the size of the gap between the lower major surface of the first CSP and the flange of the first form standard;
providing a second CSP having first and second lateral sides and upper and lower major surfaces;
providing a second form standard having a flange;
attaching the second form standard to the second CSP to dispose the second form standard along and adjacent to the upper major surface and about the first lateral side of the second CSP to dispose the flange of the second form standard beneath the lower major surface of the second CSP while leaving a gap between the lower major surface of the second CSP and the flange of the second CSP;
reducing the size of the gap between the lower major surface of the second CSP and the flange of the second form standard; and
disposing the second CSP above the first CSP.

28. The method of claim 27 further comprising attaching flex circuitry to the first form standard.

29. The method of claim 28 in which the flex circuitry is comprised of at least two conductive layers.

30. The method of claim 28 in which the flex circuitry is comprised of two flex circuits.

31. The method of claim 28 in which the flex circuitry is comprised of two flex circuits, each being comprised of at least two conductive layers.

32. The method of claim 28 in which the flex circuitry is attached to the first form standard with at least one metallic bond.

33. The method of claim 29 in which the flex circuitry is attached to the first form standard with at least one metallic bond.

34. The method of claim 30 in which the two flex circuits are each attached to the first form standard with at least one metallic bond.

35. The method of claim 31 in which the two flex circuits are each attached to the first form standard with at least one metallic bond.

36. The method of claim 27 in which the first CSP further has CSP contacts along its lower major surface, the CSP contacts rising from the lower major surface of the first CSP by a height H; and the method further comprises the step of
reducing the height H of the CSP contacts.

37. The method of claim 28 in which the first CSP further has CSP contacts along its lower major surface, the CSP contacts rising from the lower major surface of the first CSP by a height H; and the method further comprises the step of
reducing the height H of the CSP contacts.

38. The method of claim 29 in which the first CSP further has CSP contacts along its lower major surface, the CSP contacts rising from the lower major surface of the first CSP by a height H; and the method further comprising the step of
reducing the height H of the CSP contacts.

39. The method of claim 30 in which the first CSP further has CSP contacts along its lower major surface, the CSP contacts rising from the lower major surface of the first CSP by a height H; and the method further comprising the step of
reducing the height H of the CSP contacts.

40. The method of claim 31 in which the first CSP further has CSP contacts along its lower major surface, the CSP contacts rising from the lower major surface of the first CSP by a height H; and the method further comprising the step of
reducing the height H of the CSP contacts.

41. The method of claim 32 in which the first CSP further has CSP contacts along its lower major surface, the CSP contacts rising from the lower major surface of the first CSP by a height H; and the method further comprising the step of
reducing the height H of the CSP contacts.

42. The method of claim 33 in which the first CSP further has CSP contacts along its lower major surface, the CSP contacts rising from the lower major surface of the first CSP by a height of H; and the method further comprising the step of
reducing the height H of the CSP contacts.

43. The method of claim 34 in which the first CSP further has CSP contacts along its lower major surface, the CSP contacts rising from the lower major surface of the first CSP by a height of H; and the method further comprising the step of
reducing the height H of the CSP contacts.

44. The method of claim 35 in which the first CSP further has CSP contacts along its lower major surface, the CSP contacts rising from the lower major surface of the first CSP by a height of H; and the method further comprising the step of
reducing the height H of the CSP contacts.

45. The method of claim 27 in which the second CSP further has CSP contacts along its lower major surface, the CSP contacts rising from the lower major surface of the lower major surface of the second CSP by a height H; and the method further comprising the step of
reducing the height H of the CSP contacts of the second CSP.

46. The method of claim 28 in which the second CSP further has CSP contacts along its lower major surface, the CSP contacts rising from the lower major surface of the lower major surface of the second CSP by a height H; and the method further comprising the step of
reducing the height H of the CSP contacts of the second CSP.

47. The method of claim 29 in which the second CSP further has CSP contacts along its lower major surface, the CSP contacts rising from the lower major surface of the lower major surface of the second CSP by a height H; and the method further comprising the step of
reducing the height H of the CSP contacts of the second CSP.

48. The method of claim 30 in which the second CSP further has CSP contacts along its lower major surface, the CSP contacts rising from the lower major surface of the lower major surface of the second CSP by a height H; and the method further comprising the step of
reducing the height H of the CSP contacts of the second CSP.

49. The method of claim 31 in which the second CSP further has CSP contacts along its lower major surface, the CSP contacts rising from the lower major surface of the lower major surface of the second CSP by a height H; and the method further comprising the step of
reducing the height H of the CSP contacts of the second CSP.

50. A combination for devising a structure for use in a high density circuit module, the method comprising the steps of:
providing a CSP having first and second lateral sides and upper and lower major surfaces;
providing a planar metallic member;
attaching said planar metallic member to the upper major surface of the CSP so that said planar metallic member extends beyond the extent of the upper major surface of the CSP in at least one direction;
disposing a forming tool adjacent to the first lateral side of the CSP; and
deforming the planar metallic member about the forming tool to dispose a portion of the planar metallic member beneath the lower major surface of the CSP to transform the planar metallic member into a form standard disposed along and adjacent to the upper major surface and about the first lateral side of the CSP with at least one flange beneath the lower major surface of the CSP.

51. The method of claim 50 further comprising the step of attaching flex circuitry to the form standard.

52. The method of claim 51 in which the flex circuitry is comprised of at least two conductive layers.

53. The method of claim 51 in which the flex circuitry is comprised of two flex circuits.

54. The method of claim 53 in which each of the two flex circuits is comprised of two conductive layers.

55. The method of claim 51 in which the flex circuitry is attached to the form standard with at least one metallic bond.

56. The method of claim 52 in which the flex circuitry is attached to the form standard with at least one metallic bond.

57. The method of claim 53 in which the two flex circuits are each attached to the form standard with at least one metallic bond.

58. The method of claim 54 in which the two flex circuits are each attached to the form standard with at least one metallic bond.

59. A method for devising a high-density circuit module, the method comprising the steps of:
providing a first CSP having first and second lateral sides and upper and lower major surfaces;
providing a planar metallic member;
attaching said planar metallic member to the upper major surface of the first CSP so that said planar metallic member extends beyond the extent of the upper major surface of the first CSP in at least one direction;
disposing a forming tool adjacent to the first lateral side of the first CSP;
deforming the planar metallic member about the forming tool to dispose a portion of the planar metallic member beneath the lower major surface of the first CSP to transform the planar metallic member into a form standard disposed along and adjacent to the upper major surface and about the first lateral side of the first CSP with at least one flange beneath the lower major surface of the first CSP; and
disposing a second CSP above the first CSP.

60. The method of claim 59 further comprising the steps of attaching flex circuitry to the form standard and connecting the first and second CSPs with the flex circuitry.

61. The method of claim 60 in which the flex circuitry is comprised of at least two conductive layers.

62. The method of claim 60 in which the flex circuitry is comprised of two flex circuits.

63. The method of claim 62 in which each of the two flex circuits is comprised of two conductive layers.

64. The method of claim 60 in which the flex circuitry is attached to the form standard with at least one metallic bond.

65. The method of claim 61 in which the flex circuitry is attached to the form standard with at least one metallic bond.

66. The method of claim 62 in which the two flex circuits are each attached to the form standard with at least one metallic bond.

67. The method of claim 63 in which the two flex circuits are each attached to the form standard with at least one metallic bond.

68. The method of claim 50 in which the forming tool is hemispherical in shape.

69. A method for devising a high-density circuit module, the method comprising the steps of:
providing a combination in accordance with claim 1;
attaching flex circuitry to the form standard of the combination;
providing a second CSP and disposing the second CSP in stacked disposition above the combination; and
connecting the first and second CSPs with the flex circuitry.

70. A method for devising a high-density circuit module, the method comprising the steps of:
providing a first CSP having first and second lateral sides and upper and lower major surfaces;
providing a first planar metallic member and attaching said first planar metallic member to the upper major surface of the first CSP so that said first planar metallic member extends beyond the extent of the upper major surface of the first CSP;
disposing a forming tool adjacent to the first lateral side of the first CSP; and
deforming the first planar metallic member about the forming tool to dispose a portion of the first planar metallic member beneath the lower major surface of the first CSP to transform the first planar metallic member into a first form standard disposed along and adjacent to the upper major surface and about the first lateral side of the first CSP with a flange beneath the lower major surface of the first CSP;
providing a second CSP having first and second lateral sides and upper and lower major surfaces;
providing a secondary planar metallic member and attaching said planar metallic member to the upper major surface of the second CSP so that said secondary planar metallic member extends beyond the extent of the upper major surface of the second CSP;
disposing a forming tool adjacent to the first lateral side of the second CSP; and
deforming the secondary planar metallic member about the forming tool to dispose a portion of the secondary planar metallic member beneath the lower major surface of the second CSP to transform the secondary planar metallic member into a secondary form standard disposed along and adjacent to the upper major surface and about the first lateral side of the second CSP with a flange beneath the lower major surface of the second CSP;
attaching flex circuitry to the first form standard and connecting the first and second CSPs with the flex circuitry.

71. A combination for use in devising a high-density circuit module, the method comprising the steps of:
providing a CSP having first and second lateral sides and upper and lower major surfaces;
providing a form standard having a deformation area inclined to preferentially deform when under force;
attaching the form standard to the CSP to dispose the form standard along and adjacent to the upper major surface of the CSP and about the first and second lateral sides of the CSP to dispose first and second flanges of the form standard underneath portions of the lower major surface of the CSP, the form standard being dimensioned to create first and second gaps between the first and second flanges of the form standard respectively, and the lower major surface of the CSP; and
applying force to the form standard to preferentially deform the deformation area of the form standard to reduce the size of the first and second gaps.
